(19) United States
(12) Patent Application Publication
(10) Pub. No.: US 2012/0164477 A1
(43) Pub. Date: Jun. 28, 2012

(54) COATED ARTICLE AND METHOD FOR MAKING SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); LI-QUAN PENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/215,666

(22) Filed: Aug. 23, 2011

(30) Foreign Application Priority Data
Dec. 27, 2010 (CN) 201010607202.4

(51) Int. Cl. B32B 15/04; B32B 18/00; B32B 9/04; B32B 5/00; C23C 14/35; C23C 14/06

(52) U.S. Cl. 428/627; 204/192.15; 428/697; 428/469; 428/336; 428/446

(57) ABSTRACT

A coated article is provided. The coated article includes a substrate having a bonding layer, and a hard coating formed thereon, and in that order. The hard coating has a composition represented by the formula TiₓAl_{y}M_{z}N, in which the “x”, “y”, and “z” respectively represent the atomic percentage of Ti, Al, and M. The “M” is Sc or Dy. The “x”, “y” and “z” satisfy the following relationships: x+y+z=1, 35%≦x≦45%, and 0.01%≦z≦1%. A method for making the coated article is also described there.

### BACKGROUND

1. Technical Field

The exemplary disclosure generally relates to coatings, and particularly relates to an article coated with a coating, and method for manufacturing the article.

2. Description of Related Art

Physical vapor deposition (PVD) has been used to form a coating on metal bases of cutting tools or molds. Materials for PVD coating need to have excellent hardness and good oxidation resistance in high temperatures. Titanium nitride (TiN) and Titanium-aluminum nitride (TiAlN) are typically used, but are not always resistant enough to abrasion and oxidation in high temperatures to satisfy demands.

Therefore, there is room for improvement within the art.

### BRIEF DESCRIPTION OF THE FIGURES

Many aspects of the coated article can be better understood with reference to the following figures. The components in the figures are not necessarily drawn to scale, the emphasis instead being placed upon clearly illustrating the principles of the coated article. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of a coated article.

FIG. 2 is a schematic view of a magnetron sputtering machine for manufacturing the coated article in FIG. 1.

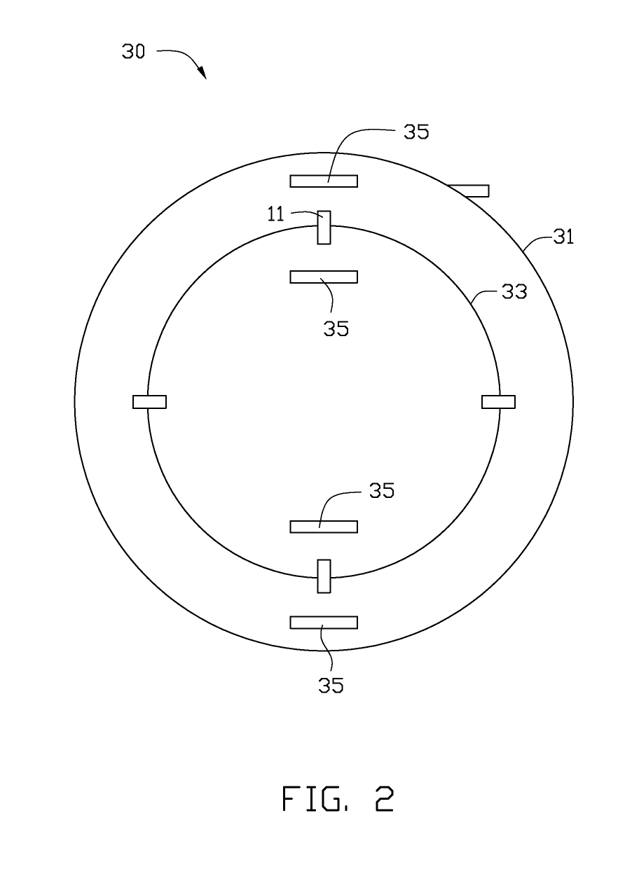

### DETAILED DESCRIPTION

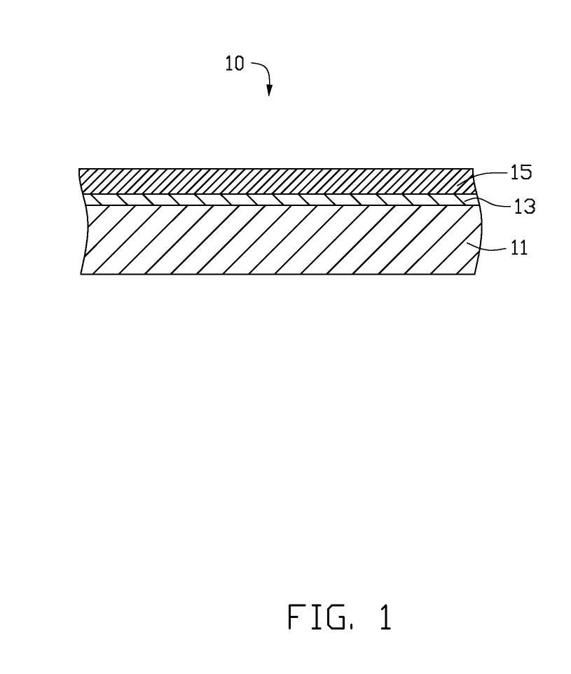

FIG. 1 shows a coated article 10 according to an exemplary embodiment. The coated article 10 includes a substrate 11 having a bonding layer 13 and a hard coating 15 formed thereon, and in that order.

The substrate 11 may be made of a hard material, such as high speed steel, hard alloy, cermet, ceramic, stainless steel, magnesium alloy, or aluminum alloy.

The bonding layer 13 has a composition represented by the formula Ti_{X}Al_{Y}M_{Z}, in which the “X”, “Y”, and “Z” represent the atomic percentage of titanium (Ti), aluminum (Al), and M respectively. The “M” may be scandium (Sc) or dysprosium (Dy). In the bonding layer 13, the “X”, “Y” and “Z” satisfy the following relationships: X+Y+Z=1, 35%≦X≦45%, and 0.01%≦Z≦1%. The bonding layer 13 may have a thickness of about 20 nanometers (nm)-50 nm. The bonding layer 13 may enhance the bond between the hard coating 15 and the substrate 11. The bonding layer 13 may be formed by magnetron sputtering.

The hard coating 15 has a composition represented by the formula TiₓAl_{y}M_{z}N, in which the “x”, “y”, and “z” respectively represent the atomic percentage of Ti, Al, and M. The “M” may be Sc or Dy. The N is nitrogen. In the hard coating 15, the “x”, “y” and “z” satisfy the following relationships: x+y+z=1, 35%≦x≦45%, and 0.01%≦z≦1%. The hard coating 15 may have a thickness of about 1.5 micrometers (μm)-3 μm. The hard coating 15 may be formed by magnetron sputtering.

The article 10 may be a cutting tool, a mold, a precision measuring tool, or a device housing.

The hard coating 15 is a TiAlN coating dopped with Sc or Dy. The surface layer of the hard coating 15 may form an aluminum oxide film in use. The Sc or Dy atoms can seal pinholes and cavities in the aluminum oxide film and prevent from oxygen entering in the hard coating 15 thus protecting the hard coating 15 from oxidation. In addition, the Sc or Dy elements react with Al element to form intermetallic compounds of Sc and Al or intermetallic compound of Dy and Al. The intermetallic compounds of Sc and Al or intermetallic compound of Dy and Al disperse in the hard coating 15 and create a dispersion-strengthening effect, thereby enhance the abrasion resistance of the hard coating 15.

An exemplary method for making the coated article 10 may include the following steps:

The substrate 11 is provided.

The substrate 11 is pretreated. The substrate 11 is cleaned with a solution (e.g., alcohol or acetone) in an ultrasonic cleaner, to remove impurities such as grease or dirt from the substrate 11. Then, the substrate 11 is dried.

The bonding layer 13 is formed on the pretreated substrate 11 by magnetron sputtering. Sputtering of the bonding layer 13 is implemented in a vacuum chamber 31 of a magnetron sputtering machine 30. The substrate 11 is held on a rotating bracket 33 in the vacuum chamber 31. The vacuum chamber 31 is fixed with composite targets 35 therein. The composite targets 35 have a composition of Ti_{X}Al_{Y}M_{Z}, which is substantially same as the composition of the bonding layer 13. Before forming the bonding layer 13, the composite targets 35 may be plasma cleaned. The plasma cleaning of the composite targets 35 may be carried out as follows.

The vacuum chamber 31 is evacuated to about 2.0×10⁻³ Pa-6.0×10⁻³ Pa. Argon is fed into the chamber at a flow rate of about 300 standard-state cubic centimeters per minute (sccm) to 500 sccm. The substrate 11 is shielded from being sputtered by a shutter (not shown). A bias voltage of about −200 V to about −300 V is applied to the substrate 11. About 3 kW-4 kW of electric power is applied to the composite targets 35. Argon is ionized to plasma. The plasma then strikes the surface of the composite targets 35 to clean the surface of the composite targets 35. Plasma cleaning the composite targets 35 may take about 5 minutes (min) to 20 min. Atoms of a surface layer of the composite targets 35 are struck by the plasma, thereby removing any impurities on the composite targets 35. The substrate 11 is unaffected by the plasma cleaning process.

Then the shutter is removed. The flow rate of the argon is adjusted to be about 120 sccm-180 sccm. The bias voltage applied to the substrate 11 is adjusted in a range between about −200 V and about −250 V. About 2.5 kW-3 kW of power is applied to the composite targets 35, depositing the bonding layer 13 on the substrate 11. The deposition of the bonding layer 13 may take about 5 min-10 min.

The hard coating 15 is directly formed on the bonding layer 13 by magnetron sputtering. Sputtering of the hard coating 15 is implemented in the vacuum chamber 31 of the magnetron sputtering machine 30. Argon and nitrogen are simultaneously fed into the vacuum chamber 31, with the argon acting as a sputtering gas and the nitrogen acting as a reaction gas. The flow rate of the argon is about 240 sccm-300 sccm. The flow rate of the nitrogen is about 75 sccm-120 sccm. A bias voltage of about −150 V to about −250 V may be applied to the substrate 11. About 3 kW-4 kW of power is applied to the composite targets 35, depositing the hard coating 15 on the bonding layer 13. The deposition of the hard coating 15 may take about 45 min-120 min.

### EXAMPLES

Experimental examples of the present disclosure are described as follows.

### Example 1

A sample of SKH51 high speed steel substrate is cleaned with alcohol in an ultrasonic cleaner for about 10 minutes and then placed into the vacuum chamber 31 of the vacuum sputtering machine 30.

The vacuum chamber 31 is evacuated to maintain an internal pressure of about 3.0×10⁻³ Pa. Argon is fed into the vacuum chamber 31 at a flow rate of about 500 sccm. A bias voltage of about −200 V is applied to the substrate. About 3 kW of power is applied to the composite targets 35 fixed in the vacuum chamber 31, plasma cleaning the composite targets 35 for about 10 min. The composite targets 35 used in example 1 have a composition of Ti_{63.98%}Al_{36%}Sc_{0.02%}.

Then the flow rate of the argon is adjusted to be about 150 sccm. The bias voltage applied to the substrate is adjusted to be −250 V. About 3 kW of power is applied to the composite targets 35, depositing a bonding layer on the substrate. The deposition of the bonding layer takes about 5 min. The bonding layer had a composition of Ti_{63.98%}Al_{36%}Sc_{0.02%}.

Argon and nitrogen were simultaneously fed into the vacuum chamber 31. The flow rate of the argon is about 300 sccm, and the flow rate of the nitrogen is about 80 sccm. A bias voltage of about −250 V is applied to the substrate. About 3 kW of electric power is applied to the composite targets 35, depositing a hard coating on the bonding layer. The deposition of the hard coating takes about 50 min. The hard coating had a composition of Ti_{63.98%}Al_{36%}Sc_{0.02%}N.

### Example 2

Example 2 is similar with the example 1 aside from the following differences. A sample of P30 hard alloy substrate is used in example 2. The composite targets 35 used in example 2 have a composition of Ti_{59.5%}Al_{40%}Sc_{0.5%}. The flow rate of the nitrogen for depositing the hard coating is about 95 sccm. The deposition of the hard layer takes about 110 min. Other parameters are same as the example 1. The bonding layer created by example 2 has a composition of Ti_{59.5%}Al_{40%}Sc_{0.5%}. The hard coating created by example 2 has a composition of Ti_{59.5%}Al_{40%}Sc_{0.5%}N.

### Example 3

Example 3 is similar with the example 1. Unlike the example 1, a sample of H13 die steel substrate is used in example 3. The composite targets 35 used in example 3 have a composition of Ti_{59.1%}Al_{40%}Sc_{0.9%}. The flow rate of the nitrogen for depositing the hard coating is about 120 sccm. The deposition of the hard layer takes about 70 min. Besides the above differences, other parameters are the same as the example 1. The bonding layer created by example 3 has a composition of Ti_{59.1%}Al_{40%}Sc_{0.9%}. The hard coating created by example 2 has a composition of Ti_{59.1%}Al_{40%}Sc_{0.9%}N.

### Examples 4-6

Examples 4-6 respectively used a sample of high speed steel substrate, a sample of hard alloy substrate, and a sample of die steel substrate. Unlike the examples 1-3, the composite targets 35 used in examples 4-6 have a composition of Ti_{X}Al_{Y}Dy_{Z}. The values of the “X” in examples 4-6 are respectively the same as the values of “X” in examples 1-3; the values of the “Y” in examples 4-6 are respectively the same as the values of “Y” in examples 1-3; and the values of the “Z” in examples 4-6 are respectively the same as the values of “Z” in examples 1-3. Other parameters of examples 4-6 were respectively the same as the example 1-3.

### Results of the Above Examples

The surface hardness and the oxidation temperature of the samples created by examples 1-6 were tested. The results are shown in Table 1. The samples created by examples 1-6 have a surface hardness equal to or greater than 32 GPa and have an oxidation temperature equal to or greater than 820° C.

TABLE 1

| | Surface hardness | Oxidation temperature |
|---|---|---|
| Examples | (GPa) | (° C.) |
| 1 | 32 | 820 |
| 2 | 33 | 830 |
| 3 | 32 | 820 |
| 4 | 34 | 850 |
| 5 | 33 | 830 |
| 6 | 32 | 820 |

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate;
a bonding layer formed on the substrate; and
a hard coating formed on the bonding layer, the hard coating having a composition represented by the formula TiₓAl_{y}M_{z}N, in which the “x”, “y”, and “z” respectively represent the atomic percentage of Ti, Al, and M, the “M” being Sc or Dy, the “x”, “y” and “z” satisfy the following relationships: x+y+z=1, 35%≦x≦45%, and 0.01%≦z≦1%.

2. The coated article as claimed in claim 1, wherein the bonding layer has a composition of Ti_{X}Al_{Y}M_{Z}, in which the “X”, “Y”, and “Z” respectively represent the atomic percentage of Ti, Al, and M, the “M” being Sc or Dy, the “X”, “Y” and “Z” satisfy the following relationships: X+Y+Z=1, 35%≦X≦45%, and 0.01%≦Z≦1%.

3. The coated article as claimed in claim 1, wherein the bonding layer has a thickness of about 20 nm-50 nm.

4. The coated article as claimed in claim 1, wherein the hard coating has a thickness of about 1.5 μm-3 μm.

5. The coated article as claimed in claim 1, wherein the bonding layer and the hard coating both are formed by magnetron sputtering.

6. The coated article as claimed in claim 1, wherein the substrate is made of material selected from the group consisting of high speed steel, hard alloy, cermet, ceramic, stainless steel, magnesium alloy, and aluminum alloy.

7. A method for making a coated article, comprising:
providing a substrate;
forming a bonding layer on the substrate by magnetron sputtering; and
forming a hard coating on the bonding layer by magnetron sputtering, the hard coating having a composition represented by the formula TiₓAl_{y}M_{z}N, in which the “x”, “y”, and “z” respectively represent the atomic percentage of Ti, Al, and M, the “M” being Sc or Dy, the “x”, “y” and “z” satisfy the following relationships: x+y+z=1, 35%≦x≦45%, and 0.01%≦z≦1%.

8. The method as claimed in claim 7, wherein magnetron sputtering the bonding layer and the hard coating uses composite targets having a composition of Ti_{X}Al_{Y}M_{Z}, in which the “X”, “Y”, and “Z” respectively represent the atomic percentage of Ti, Al, and M, the “M” being Sc or Dy, the “X”, “Y” and “Z” satisfy the following relationships: X+Y+Z=1, 35%≦X≦45%, and 0.01%≦Z≦1%.

9. The method as claimed in claim 8, wherein during magnetron sputtering of the bonding layer, argon is used as a sputtering gas; about 2.5 kW-3 kW of power is applied to composite targets; a bias voltage of about −200 V to about −250 V is applied to the substrate.

10. The method as claimed in claim 8, wherein magnetron sputtering of the bonding layer takes about 5 min-10 min.

11. The method as claimed in claim 7, wherein during magnetron sputtering of the hard coating, argon is used as a sputtering gas; nitrogen at a flow rate of about 75 sccm-120 sccm is used as a reaction gas; about 3 kW-4 kW of power is applied to composite targets; a bias voltage of about −150 V to about −250 V is applied to the substrate.

12. The method as claimed in claim 11, wherein magnetron sputtering of the hard coating takes about 45 min-120 min.
